(19) United States
(12) Patent Application Publication
(10) Pub. No.: US 2025/0274112 A1
(43) Pub. Date: Aug. 28, 2025

(54) CLOCK SIGNAL DUTY RATIO CORRECTION CIRCUIT AND METHOD OF CORRECTING DUTY RATIO

(71) Applicant: Richtek Technology Corporation, Zhubei City (TW)

(72) Inventor: Chia-Jung Chang, Hsinchu (TW)

(21) Appl. No.: 18/656,733

(22) Filed: May 7, 2024

(30) Foreign Application Priority Data
Feb. 23, 2024 (TW) 113106634

(51) Int. Cl. H03K 5/156

(52) U.S. Cl. CPC H03K 5/1565

(57) ABSTRACT

A clock signal duty ratio correction circuit includes: a period indication signal generation circuit configured to operably generate a period indication signal according to a clock signal, wherein a period indication level of the period indication signal is correlated with a period time of the clock signal; a first ramp signal generation circuit configured to operably generate a first ramp signal according to the clock signal; and a clock signal regeneration circuit configured to operably generate a clock regeneration signal according to a triggering of the clock signal and according to a comparison between the first ramp signal and the period indication level, such that the clock regeneration signal has a target duty ratio; wherein a slope of the first ramp signal is correlated with the target duty ratio.

### CROSS REFERENCE

The present invention claims priority to the TW patent application Ser. No. 113106634, filed on Feb. 23, 2024.

### BACKGROUND OF THE PRESENT INVENTION

### Field of Invention

The present invention relates to a clock signal duty ratio correction circuit and a method of correcting duty ratio, and particularly to a clock signal duty ratio correction circuit that can be coupled and synchronized with at least one other clock signal duty ratio correction circuit, and its method of correcting duty ratio.

### Description of Related Art

FIG. 1 illustrates a circuit schematic diagram of a conventional light-emitting diode (LED) driver circuit. As shown in FIG. 1, the conventional LED driver circuit 1 includes a main circuit 11 and operation circuits 10[1], 10[2] and 10[3]. The operation circuits 10[1], 10[2] and 10[3] are interconnected in a daisy chain topology to transmit a clock signal clk and a data signal dt. More specifically, a clock signal, clk1, received at an input of the operation circuit 10[1], is inverted and transmitted as clk2 to an input of the operation circuit 10[2]. Subsequently, clk2 is inverted and transmitted as clk3 to an input of the operation circuit 10[3]. Additionally, a data signal, dt1, received at another input of the operation circuit 10[1], is transmitted as dt2 to another input of the operation circuit 10[2]. Then, dt2 is transmitted as dt3 to another input of the operation circuit 10[3]. Finally, dt3 is transmitted back to the main circuit 11. Note that the clock signal clk is a collective reference to the series of clock signals clk1, clk2, and clk3, each corresponding to different operation circuits 10[1], 10[2] and 10[3] in a sequential configuration.

As depicted, due to a logic inverter in each stage of the operation circuits 10[1], 10[2], and 10[3], the clock signal clk1 received at the input of the operation circuit 10[1] is not perfectly symmetrical with the clock signal clk2 passed to the operation circuit 10[2] due to a rising time and a falling time of the clock signal clk caused by an operation of the logic inverter of the operation circuit 10[1]. This asymmetry of the clock signals clk1 and clk2 at different stages becomes more pronounced as more operation circuits are interconnected, thereby altering a duty ratio of the clock signal clk increasingly away from its initial value, such as 50%, and consequently reducing communication quality between the operation circuits.

To address the issue of duty ratio changes of the clock signals in a daisy chain topology, U.S. Pat. Nos. 7,221,204B2, 7,570,094B2, 8,248,130B2, 8,552,778B2, 8,803,577B2, 10,205,445B1, 10,560,080B1, and 11,539,369B2 propose solutions and circuits. However, these methods and circuits require additional complex circuitry, significantly increasing manufacturing costs.

In view of this, the present invention introduces an innovative clock signal duty ratio correction circuit and a method of correcting duty ratio that do not require complex circuitry to prevent the aforementioned changes in duty ratio.

### SUMMARY OF THE PRESENT INVENTION

In one aspect, the present invention provides a clock signal duty ratio correction circuit including: a period indication signal generation circuit configured to generate a period indication signal according to a clock signal, wherein a period indication level of the period indication signal is correlated with a period time of the clock signal; a first ramp signal generation circuit configured to generate a first ramp signal according to the clock signal; and a clock signal regeneration circuit configured to generate a clock regeneration signal according to a triggering of the clock signal and a comparison of the first ramp signal with the period indication level, such that the clock regeneration signal has a target duty ratio; wherein a slope of the first ramp signal is correlated with the target duty ratio.

In one embodiment, the first ramp signal generation circuit charges a first capacitor with a first current to generate the first ramp signal, wherein the first current is inversely correlated with the target duty ratio, or a first capacitance of the first capacitor is positively correlated with the target duty ratio.

In one embodiment, the clock signal duty ratio correction circuit further includes a frequency divider circuit coupled with the period indication signal generation circuit, configured to divide a frequency of the clock signal and generate a frequency divided clock signal.

In one embodiment, the period indication signal generation circuit includes a second ramp signal generation circuit configured to charge a second capacitor with a second current for the period time according to the frequency divided clock signal to generate a second ramp signal, wherein the second ramp signal corresponds to the period indication signal, wherein a peak of the second ramp signal corresponds to the period indication level.

In one embodiment, a ratio of the first current to the second current is positively correlated with the target duty ratio, and/or a ratio of the first capacitance to a second capacitance of the second capacitor is inversely correlated with the target duty ratio.

In one embodiment, the period indication signal generation circuit further includes a third ramp signal generation circuit configured to charge a third capacitor with a third current for the period time according to the frequency divided clock signal to generate a third ramp signal, wherein the third ramp signal corresponds to the period indication signal, wherein a peak of the third ramp signal corresponds to the period indication level, wherein the second ramp signal and the third ramp signal have a phase difference of 180 degrees.

In one embodiment, the clock signal regeneration circuit includes a comparison circuit configured to compare the first ramp signal with the second ramp signal, and compare the first ramp signal with the third ramp signal respectively, to generate the clock regeneration signal.

In one embodiment, the first ramp signal generation circuit further includes a first ramp timing determination circuit configured to determine a first charging start point of the first ramp signal according to a state transition point of the clock signal, and to determine a timing end point of the first ramp signal according to a first comparison result and a second comparison result, wherein the first comparison result is generated after comparing the first ramp signal with the second ramp signal, wherein the second comparison result is generated after comparing the first ramp signal with the third ramp signal, wherein the target duty ratio corresponds to a ratio of a time difference between the first charging start point and the subsequent timing end point to the period time, wherein the state transition point is one of a rising edge or a falling edge of the clock signal.

In one embodiment, the second ramp signal generation circuit begins charging the second capacitor with the second current at a first division state transition point of the frequency divided clock signal, stops charging the second capacitor with the second current at a second division state transition point of the frequency divided clock signal, maintains a voltage across the second capacitor at the period indication level, and resets the second ramp signal according to the first comparison result; wherein the third ramp signal generation circuit begins charging the third capacitor with the third current at the second division state transition point of the frequency divided clock signal, stops charging the third capacitor with the third current at the first division state transition point of the frequency divided clock signal, maintains a voltage across the third capacitor at the period indication level, and resets the third ramp signal according to the second comparison result; wherein the first division state transition point is one of a rising edge or a falling edge of the frequency divided clock signal, wherein the second division state transition point is another of the rising edge or the falling edge of the frequency divided clock signal.

In one embodiment, the second ramp signal generation circuit further delays resetting the second ramp signal by a first delay time according to the first comparison result; wherein the third ramp signal generation circuit further delays resetting the third ramp signal by a second delay time according to the second comparison result.

In one embodiment, the clock signal duty ratio correction circuit is applied to plural operation circuits coupled to one another in a daisy chain topology, wherein each of the plural operation circuits generates a corresponding output clock signal according to a corresponding input clock signal, wherein the corresponding output clock signal serves as the corresponding input clock signal for an adjacent next operation circuit of the plural operation circuits; wherein each of the plural operation circuits includes the clock signal duty ratio correction circuit, wherein the clock signal duty ratio correction circuit is configured to generate the clock regeneration signal according to the input clock signal, and to generate the output clock signal according to the clock regeneration signal.

In one embodiment, each of the plural operation circuits includes at least one state circuit, wherein the at least one state circuit is configured to latch at least one state of the at least one state circuit according to a triggering of the corresponding clock regeneration signal, wherein the at least one state circuit is coupled in a daisy chain topology with at least one state circuit of the adjacent next operation circuit of the plural operation circuits.

In another aspect, the present invention provides a duty ratio correction method for correcting a duty ratio of a clock signal, the duty ratio correction method including: generating a period indication signal according to the clock signal, wherein a period indication level of the period indication signal is correlated with a period time of the clock signal; generating a first ramp signal according to the clock signal; and generating a clock regeneration signal according to a triggering of the clock signal and a comparison of the first ramp signal with the period indication level, such that the clock regeneration signal has a target duty ratio; wherein a slope of the first ramp signal is correlated with the target duty ratio.

In one embodiment, the step of generating the first ramp signal according to the clock signal includes: charging a first capacitor with a first current to generate the first ramp signal, wherein the first current is inversely correlated with the target duty ratio, or a first capacitance of the first capacitor is positively correlated with the target duty ratio.

In one embodiment, the duty ratio correction method further includes: dividing the clock signal to generate a frequency divided clock signal.

In one embodiment, the step of generating the period indication signal according to the clock signal includes: charging a second capacitor with a second current for the period time according to the frequency divided clock signal to generate a second ramp signal, wherein the second ramp signal corresponds to the period indication signal, wherein a peak of the second ramp signal corresponds to the period indication level.

In one embodiment, a ratio of the first current to the second current is positively correlated with the target duty ratio, and/or a ratio of the first capacitance to a second capacitance of the second capacitor is inversely correlated with the target duty ratio.

In one embodiment, the step of generating the period indication signal according to the clock signal further includes: charging a third capacitor with a third current for the period time according to the frequency divided clock signal to generate a third ramp signal, wherein the third ramp signal corresponds to the period indication signal, wherein a peak of the third ramp signal corresponds to the period indication level, wherein the second ramp signal and the third ramp signal have a phase difference of 180 degrees.

In one embodiment, the step of generating the clock regeneration signal according to the triggering of the clock signal and a comparison of the first ramp signal with the period indication level includes: comparing the first ramp signal with the second ramp signal and comparing the first ramp signal with the third ramp signal respectively, to generate the clock regeneration signal.

In one embodiment, the step of generating the first ramp signal according to the clock signal further includes: determining a first charging start point of the first ramp signal according to a state transition point of the clock signal, and determining a timing end point of the first ramp signal according to a first comparison result and a second comparison result, wherein the first comparison result is generated after comparing the first ramp signal with the second ramp signal, wherein the second comparison result is generated after comparing the first ramp signal with the third ramp signal, wherein the target duty ratio corresponds to a ratio of a time difference between the first charging start point and the subsequent timing end point to the period time, wherein the state transition point is one of a rising edge or a falling edge of the clock signal.

In one embodiment, at a first division state transition point of the frequency divided clock signal, the second current begins charging the second capacitor, and at a second division state transition point of the frequency divided clock signal, the second current stops charging the second capacitor, maintains a voltage across the second capacitor at the period indication level, and resets the second ramp signal according to the first comparison result; wherein at the second division state transition point of the frequency divided clock signal, the third current begins charging the third capacitor, and at the first division state transition point of the frequency divided clock signal, the third current stops charging the third capacitor, maintains a voltage across the third capacitor at the period indication level, and resets the third ramp signal according to the second comparison result; wherein the first division state transition point is one of a rising edge or a falling edge of the frequency divided clock signal, wherein the second division state transition point is another of the rising edge or the falling edge of the frequency divided clock signal.

In one embodiment, the step of resetting the second ramp signal according to the first comparison result further includes: delaying resetting the second ramp signal by a first delay time according to the first comparison result; wherein the step of resetting the third ramp signal according to the second comparison result further includes: delaying resetting the third ramp signal by a second delay time according to the second comparison result.

In one embodiment, the duty ratio correction method is utilized for a clock signal duty ratio correction circuit which is applied to plural operation circuits coupled to one another in a daisy chain topology, wherein each of the plural operation circuits generates a corresponding output clock signal according to a corresponding input clock signal, wherein the corresponding output clock signal serves as the corresponding input clock signal for an adjacent next operation circuit of the plural operation circuits; wherein each of the plural operation circuits includes the clock signal duty ratio correction circuit, wherein the clock signal duty ratio correction circuit is configured to generate the clock regeneration signal according to the input clock signal, and to generate the output clock signal according to the clock regeneration signal.

In one embodiment, each of the plural operation circuits includes at least one state circuit, wherein the at least one state circuit is configured to latch at least one state of the at least one state circuit according to a triggering of the corresponding clock regeneration signal, wherein the at least one state circuit is coupled in a daisy chain topology with at least one state circuit of the adjacent next operation circuit of the plural operation circuits.

One advantage of the present invention is that the present invention can prevent changes in the duty ratio.

This document has detailed the present invention through specific embodiments. However, these descriptions are intended to facilitate understanding the of present invention's objectives, technical contents, features, and achieved effects, rather than to limit the scope of the present invention. Various combinations and equivalent variations, under the spirit of the present invention, can be conceived by those skilled in the art without departing from the scope and spirit of the present invention.

### BRIEF DESCRIPTION OF THE DRAWINGS

FIG. 1 illustrates a circuit schematic diagram of a conventional LED driver circuit.

FIG. 2 illustrates a circuit schematic diagram of an LED driver circuit with a clock signal duty ratio correction circuit according to one embodiment of the present invention.

FIG. 3 illustrates a circuit schematic diagram of the clock signal duty ratio correction circuit according to one embodiment of the present invention.

FIGS. 4-6 illustrate signal waveform diagrams of related signals of the clock signal duty ratio correction circuit of FIG. 3 according to embodiments of the present invention.

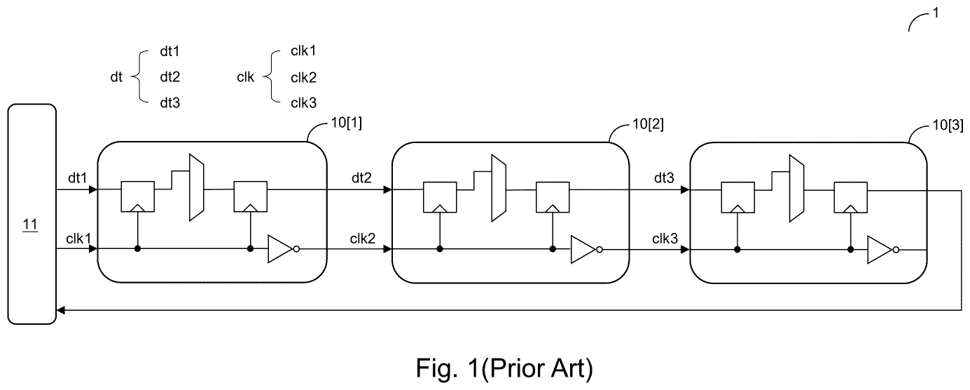

### DESCRIPTION OF THE PREFERRED EMBODIMENTS

The drawings as referred to throughout the description of the present invention are for illustration only, to show the interrelations between the circuits and the signal waveforms, but not drawn according to actual scale of circuit sizes and signal amplitudes and frequencies.

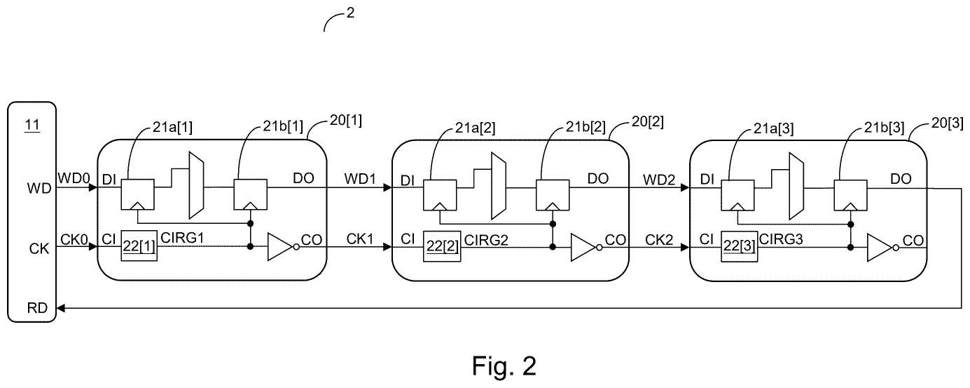

FIG. 2 illustrates a circuit schematic diagram of an LED driver circuit with a clock signal duty ratio correction circuit according to one embodiment of the present invention. As shown in FIG. 2, the LED driver circuit 2 includes a main circuit 11 and operation circuits 20[1], 20[2], and 20[3]. The operation circuits 20[1], 20[2], and 20[3] are coupled to one another in a daisy chain topology, so as to transmit clock signals from pin CK of the main circuit 11 to each of the operation circuits 20[1], 20[2], and 20[3], and to transmit and receive data at pins WD and RD of the main circuit 11 to and from each of the operation circuits 20[1], 20[2], and 20[3]. The clock signal duty ratio correction circuits 22[1], 22[2], 22[3] are applied within the plural operation circuits 20[1], 20[2], 20[3] coupled to one another in a daisy chain topology. Each of the plural operation circuits 20[1], 20[2], and 20[3], such as the operation circuit 20[1], generates a corresponding output clock signal CK1 according to the corresponding input clock signal CK0, wherein the corresponding output clock signal CK1 serves as the corresponding input clock signal for an adjacent operation circuit in the next stage, such as the operation circuit 20[2]. Each of the plural operation circuits 20[1], 20[2], and 20[3] includes a clock signal duty ratio correction circuit. For instance, the operation circuit 20[1] includes the clock signal duty ratio correction circuit 22[1], the operation circuit 20[2] includes the clock signal duty ratio correction circuit 22[2], and the operation circuit 20[3] includes the clock signal duty ratio correction circuit 22[3]. The clock signal duty ratio correction circuit 22[1] is configured to generate a clock regeneration signal CIRG1 according to the input clock signal CK0 and to generate the output clock signal CK1 according to the clock regeneration signal CIRG1. The clock signal duty ratio correction circuit 22[2] is configured to generate a clock regeneration signal CIRG2 according to the input clock signal CK1 and to generate the output clock signal CK2 according to the clock regeneration signal CIRG2. The clock signal duty ratio correction circuit 22[3] is configured to generate a clock regeneration signal CIRG3 according to the input clock signal CK2. In one embodiment, the output clock signal generated according to the clock regeneration signal CIRG3 can be returned to the main circuit 11. In another embodiment, the output clock signal may not be generated according to the clock regeneration signal CIRG3, meaning that the output clock signal is not returned to the main circuit 11.

It should be noted that a pin DI is utilized as the data input pin, a pin DO as the data output pin, a pin CI as the clock signal input pin, and a pin CO as the clock signal output pin.

Each of the plural operation circuits includes at least one state circuit. For example, the operation circuit 20[1] includes at least one state circuit 21a[1] and 21b[1], the operation circuit 20[2] includes at least one state circuit 21a[2] and 21b[2], and the operation circuit 20[3] includes at least one state circuit 21a[3] and 21b[3]. The at least one state circuit 21a[1] and 21b[1] are triggered by the corresponding clock regeneration signal CIRG1 to latch the at least one state of the at least one state circuit 21a[1] and 21b[1]. The at least one state circuit 21a[2] and 21b[2] are triggered by the corresponding clock regeneration signal CIRG2 to latch the at least one state of the at least one state circuit 21a[2] and 21b[2]. The at least one state circuit 21a[3] and 21b[3] are triggered by the corresponding clock regeneration signal CIRG3 to latch the at least one state of the at least one state circuit 21a[3] and 21b[3]. The at least one state circuit 21a[1] is coupled in a daisy chain topology with the at least one corresponding state circuit 21a[2] of an adjacent operation circuit 20[2], and the at least one state circuit 21a[2] is coupled in the daisy chain topology with the at least one corresponding state circuit 21a[3] of an adjacent operation circuit 20[3].

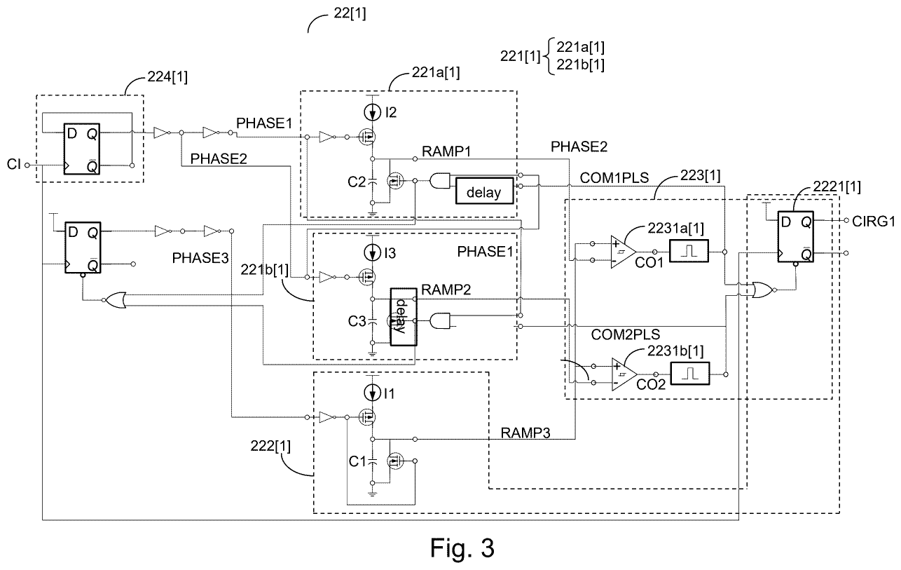

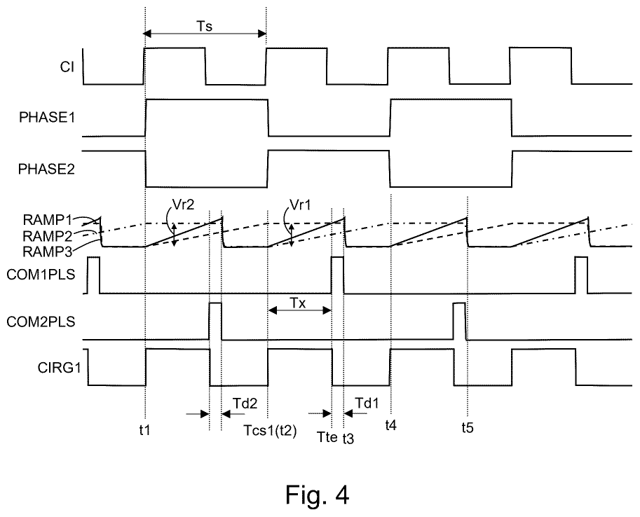

FIG. 3 illustrates a circuit schematic diagram of the clock signal duty ratio correction circuit according to one embodiment of the present invention. As shown in FIG. 3, the clock signal duty ratio correction circuit 22[1] includes a period indication signal generation circuit 221[1], a first ramp signal generation circuit 222[1], and a clock signal regeneration circuit 223[1]. The period indication signal generation circuit 221[1] is configured to generate period indication signals RAMP1 and RAMP2 according to a clock signal CI. Please refer to FIGS. 4 and 3. In one embodiment, period indication signal levels Vr1 and Vr2 of the period indication signals RAMP1 and RAMP2 are correlated with a period time Ts of the clock signal CI. Referring to FIG. 3, the first ramp signal generation circuit 222[1] is configured to generate a first ramp signal RAMP3 according to the clock signal CI. The clock signal regeneration circuit 223[1] is configured to generate the clock regeneration signal CIRG1, triggered by the clock signal CI and according to a comparison between the first ramp signal RAMP3 and the period indication signal levels Vr1 and Vr2, such that the clock regeneration signal CIRG1 has a target duty ratio. In one embodiment, a slope of the first ramp signal RAMP3 is correlated with the target duty ratio.

The first ramp signal generation circuit 222[1] charges a first capacitor C1 with a first current I1 to generate the first ramp signal RAMP3. In one embodiment, the first current I1 is inversely correlated with the target duty ratio, or the first capacitance of the first capacitor C1 is positively correlated with the target duty ratio.

As shown in FIG. 3, the clock signal duty ratio correction circuit 22[1] also includes a frequency divider circuit 224[1], which is coupled to the period indication signal generation circuit 221[1] and is configured to perform division on the clock signal CI and generate frequency divided clock signals PHASE1 and PHASE2.

The period indication signal generation circuit 221[1] includes a second ramp signal generation circuit 221a[1], which is configured to charge a second capacitor C2 with a second current I2 for one period time Ts according to the frequency divided clock signal PHASE1 to generate the second ramp signal RAMP1. The second ramp signal RAMP1 corresponds to the period indication signals RAMP1 and RAMP2, and a peak of the second ramp signal RAMP1 corresponds to the period indication signal level Vr1.

In one embodiment, the ratio of the first current I1 to the second current I2 is positively correlated with the target duty ratio, and/or the ratio of the first capacitance to the second capacitance of the second capacitor C2 is inversely correlated with the target duty ratio.

As shown in FIG. 3, the period indication signal generation circuit 221[1] further includes a third ramp signal generation circuit 221b[1], which is configured to charge a third capacitor C3 with a third current I3 for one period time Ts according to the frequency divided clock signal PHASE2 to produce the third ramp signal RAMP2. The third ramp signal RAMP2 corresponds to the period indication signals RAMP1 and RAMP2. A peak of the third ramp signal RAMP2 corresponds to the period indication signal level Vr2. In one embodiment, the second ramp signal RAMP1 and the third ramp signal RAMP2 have a phase difference of 180 degrees.

The clock signal regeneration circuit 223[1] includes comparison circuits 2231a[1] and 2231b[1], which are configured to compare the first ramp signal RAMP3 with the second ramp signal RAMP1, and the first ramp signal RAMP3 with the third ramp signal RAMP2, respectively, to generate the clock regeneration signal CIRG1.

More specifically, the comparison circuit 2231a[1] compares the first ramp signal RAMP3 with the second ramp signal RAMP1 to generate a first comparison result CO1. A pulse generator of the clock signal regeneration circuit 223[1] receives the first comparison result CO1 to generate a pulse signal COM1PLS. The comparison circuit 2231b[1] compares the first ramp signal RAMP3 with the third ramp signal RAMP2 to generate a second comparison result CO2. Another pulse generator of the clock signal regeneration circuit 223[1] receives the second comparison result CO2 to generate a pulse signal COM2PLS. After a logic operation (such as a logic NOR operation) is performed on the pulse signals COM1PLS and COM2PLS, and when the clock signal CI is enabled, the clock regeneration signal CIRG1 is generated. After the pulse signal COM1PLS is delayed by a delay circuit of the second ramp signal generation circuit 221a[1], a logic operation is performed to the frequency divided clock signal PHASE2 and the delayed pulse signal COM1PLS, so as to determine the second ramp signal RAMP1. In a similar way, after the pulse signal COM2PLS is delayed by a delay circuit of the third ramp signal generation circuit 221b[1], a logic operation is performed to the frequency divided clock signal PHASE1 and the delayed pulse signal COM2PLS, so as to determined the third ramp signal RAMP2.

Referring to FIGS. 3 and 4, the first ramp signal generation circuit 222[1] further includes a first ramp timing determination circuit 2221[1], which is configured to determine a first charging start point Tcs1 of the first ramp signal RAMP3 according to a state transition point of the clock signal CI, and determine a timing end point Tte of the first ramp signal RAMP3 according to the first comparison result CO1 and the second comparison result CO2, wherein the first comparison result CO1 is generated after comparing the first ramp signal RAMP3 with the second ramp signal RAMP1, and the second comparison result CO2 is generated after comparing the first ramp signal RAMP3 with the third ramp signal RAMP2. Please refer to FIGS. 3 and 4. In one embodiment, the target duty ratio corresponds to a ratio of a time difference Tx between the first charging start point Tcs1 and the subsequent timing end point Tte to the period time Ts. In one embodiment, the state transition point is either a rising edge or a falling edge of the clock signal CI.

Referring to FIGS. 3 and 4, the second ramp signal generation circuit 221a[1] begins charging the second capacitor C2 with the second current I2 at a first division state transition point t1 of the frequency divided clock signal PHASE1, and stops charging the second capacitor C2 with the second current I2 at a second division state transition point t2 of the frequency divided clock signal PHASE1, maintaining the voltage across the second capacitor C2 at the period indication signal level Vr1. The second ramp signal generation circuit 221a[1] resets the second ramp signal RAMP1 at a time point t3 according to the first comparison result CO1. The third ramp signal generation circuit 221b[1] begins charging the third capacitor C3 with the third current I3 at the second division state transition point t2 of the frequency divided clock signal PHASE1, and stops charging the third capacitor C3 with the third current I3 at a first division state transition point t4 of the frequency divided clock signal PHASE1, maintaining the voltage across the third capacitor C3 at the period indication signal level Vr2. The third ramp signal generation circuit 221b[1] resets the third ramp signal RAMP2 at a time point t5 according to the second comparison result CO2. The first and second division state transition points t1 and t4 correspond to either two rising edges or two falling edges of the frequency divided clock signal PHASE1, whereas the second division state transition point t2 corresponds to an opposite edge to the rising or falling edge corresponding to the first division state transition point t1.

As shown in FIGS. 3 and 4, the second ramp signal generation circuit 221a[1] delays resetting the second ramp signal RAMP1 by a first delay time Td1 according to the first comparison result CO1, while the third ramp signal generation circuit 221b[1] delays resetting the third ramp signal RAMP2 by a second delay time Td2 according to the second comparison result CO2.

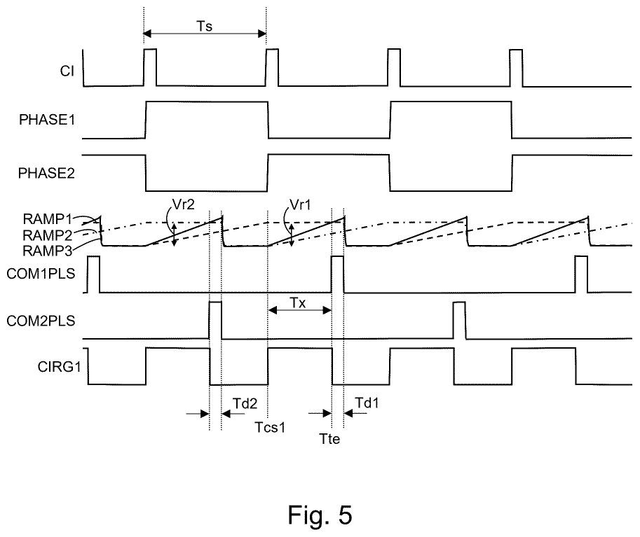

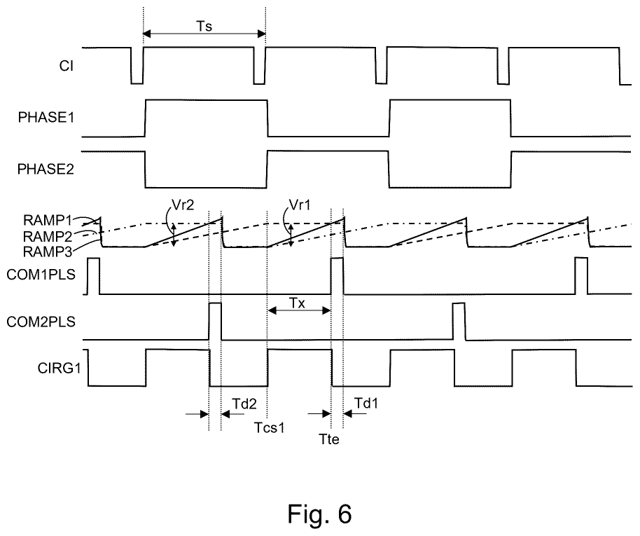

FIGS. 4-6 illustrate signal waveform diagrams of related signals of the clock signal duty ratio correction circuit of FIG. 3 according to embodiments of the present invention. The frequency divided clock signals PHASE1, PHASE2, the second ramp signal RAMP1, the third ramp signal RAMP2, the first ramp signal RAMP3, and the clock regeneration signal CIRG1 are shown in FIGS. 4-6. FIG. 4 illustrates an embodiment wherein a duty ratio of the clock signal CI is 50.2%, FIG. 5 illustrates an embodiment where the duty ratio of the clock signal CI is 10.2%, and FIG. 6 illustrates an embodiment where the duty ratio of the clock signal CI is 90.2%. As shown in FIGS. 4-6, when the first ramp signal RAMP3 is larger than the second ramp signal RAMP1, the signal COM1PLS is at an enabled level. When the first ramp signal RAMP3 is larger than the third ramp signal RAMP2, the signal COM2PLS is at an enable level.

In summary, the present invention prevents changes in the duty ratio through the clock signal duty ratio correction circuit.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents.

What is claimed is:

1. A clock signal duty ratio correction circuit comprising:
a period indication signal generation circuit configured to generate a period indication signal according to a clock signal, wherein a period indication level of the period indication signal is correlated with a period time of the clock signal;
a first ramp signal generation circuit configured to generate a first ramp signal according to the clock signal; and
a clock signal regeneration circuit configured to generate a clock regeneration signal according to a triggering of the clock signal and a comparison of the first ramp signal with the period indication level, such that the clock regeneration signal has a target duty ratio;
wherein a slope of the first ramp signal is correlated with the target duty ratio.

2. The clock signal duty ratio correction circuit of claim 1, wherein the first ramp signal generation circuit charges a first capacitor with a first current to generate the first ramp signal, wherein the first current is inversely correlated with the target duty ratio, or a first capacitance of the first capacitor is positively correlated with the target duty ratio.

3. The clock signal duty ratio correction circuit of claim 2, further comprising a frequency divider circuit coupled with the period indication signal generation circuit, configured to divide a frequency of the clock signal and generate a frequency divided clock signal.

4. The clock signal duty ratio correction circuit of claim 3, wherein the period indication signal generation circuit includes a second ramp signal generation circuit configured to charge a second capacitor with a second current for the period time according to the frequency divided clock signal to generate a second ramp signal, wherein the second ramp signal corresponds to the period indication signal, wherein a peak of the second ramp signal corresponds to the period indication level.

5. The clock signal duty ratio correction circuit of claim 4, wherein a ratio of the first current to the second current is positively correlated with the target duty ratio, and/or a ratio of the first capacitance to a second capacitance of the second capacitor is inversely correlated with the target duty ratio.

6. The clock signal duty ratio correction circuit of claim 5, wherein the period indication signal generation circuit further includes a third ramp signal generation circuit configured to charge a third capacitor with a third current for the period time according to the frequency divided clock signal to generate a third ramp signal, wherein the third ramp signal corresponds to the period indication signal, wherein a peak of the third ramp signal corresponds to the period indication level, wherein the second ramp signal and the third ramp signal have a phase difference of 180 degrees.

7. The clock signal duty ratio correction circuit of claim 6, wherein the clock signal regeneration circuit includes a comparison circuit configured to compare the first ramp signal with the second ramp signal, and compare the first ramp signal with the third ramp signal respectively, to generate the clock regeneration signal.

8. The clock signal duty ratio correction circuit of claim 7, wherein the first ramp signal generation circuit further includes a first ramp timing determination circuit configured to determine a first charging start point of the first ramp signal according to a state transition point of the clock signal, and to determine a timing end point of the first ramp signal according to a first comparison result and a second comparison result, wherein the first comparison result is generated after comparing the first ramp signal with the second ramp signal, wherein the second comparison result is generated after comparing the first ramp signal with the third ramp signal, wherein the target duty ratio corresponds to a ratio of a time difference between the first charging start point and the subsequent timing end point to the period time, wherein the state transition point is one of a rising edge or a falling edge of the clock signal.

9. The clock signal duty ratio correction circuit of claim 8, wherein the second ramp signal generation circuit begins charging the second capacitor with the second current at a first division state transition point of the frequency divided clock signal, stops charging the second capacitor with the second current at a second division state transition point of the frequency divided clock signal, maintains a voltage across the second capacitor at the period indication level, and resets the second ramp signal according to the first comparison result;
wherein the third ramp signal generation circuit begins charging the third capacitor with the third current at the second division state transition point of the frequency divided clock signal, stops charging the third capacitor with the third current at the first division state transition point of the frequency divided clock signal, maintains a voltage across the third capacitor at the period indication level, and resets the third ramp signal according to the second comparison result;
wherein the first division state transition point is one of a rising edge or a falling edge of the frequency divided clock signal, wherein the second division state transition point is another of the rising edge or the falling edge of the frequency divided clock signal.

10. The clock signal duty ratio correction circuit of claim 9, wherein the second ramp signal generation circuit further delays resetting the second ramp signal by a first delay time according to the first comparison result; wherein the third ramp signal generation circuit further delays resetting the third ramp signal by a second delay time according to the second comparison result.

11. The clock signal duty ratio correction circuit of claim 1, wherein the clock signal duty ratio correction circuit is applied to plural operation circuits coupled to one another in a daisy chain topology, wherein each of the plural operation circuits generates a corresponding output clock signal according to a corresponding input clock signal, wherein the corresponding output clock signal serves as the corresponding input clock signal for an adjacent next operation circuit of the plural operation circuits;
wherein each of the plural operation circuits includes the clock signal duty ratio correction circuit, wherein the clock signal duty ratio correction circuit is configured to generate the clock regeneration signal according to the input clock signal, and to generate the output clock signal according to the clock regeneration signal.

12. The clock signal duty ratio correction circuit of claim 11, wherein each of the plural operation circuits includes at least one state circuit, wherein the at least one state circuit is configured to latch at least one state of the at least one state circuit according to a triggering of the corresponding clock regeneration signal, wherein the at least one state circuit is coupled in a daisy chain topology with at least one state circuit of the adjacent next operation circuit of the plural operation circuits.

13. A duty ratio correction method for correcting a duty ratio of a clock signal, the duty ratio correction method comprising:
generating a period indication signal according to the clock signal, wherein a period indication level of the period indication signal is correlated with a period time of the clock signal;
generating a first ramp signal according to the clock signal; and
generating a clock regeneration signal according to a triggering of the clock signal and a comparison of the first ramp signal with the period indication level, such that the clock regeneration signal has a target duty ratio;
wherein a slope of the first ramp signal is correlated with the target duty ratio.

14. The duty ratio correction method of claim 13, wherein the step of generating the first ramp signal according to the clock signal includes: charging a first capacitor with a first current to generate the first ramp signal, wherein the first current is inversely correlated with the target duty ratio, or a first capacitance of the first capacitor is positively correlated with the target duty ratio.

15. The duty ratio correction method of claim 14, further comprising: dividing the clock signal to generate a frequency divided clock signal.

16. The duty ratio correction method of claim 15, wherein the step of generating the period indication signal according to the clock signal includes: charging a second capacitor with a second current for the period time according to the frequency divided clock signal to generate a second ramp signal, wherein the second ramp signal corresponds to the period indication signal, wherein a peak of the second ramp signal corresponds to the period indication level.

17. The duty ratio correction method of claim 16, wherein a ratio of the first current to the second current is positively correlated with the target duty ratio, and/or a ratio of the first capacitance to a second capacitance of the second capacitor is inversely correlated with the target duty ratio.

18. The duty ratio correction method of claim 17, wherein the step of generating the period indication signal according to the clock signal further includes: charging a third capacitor with a third current for the period time according to the frequency divided clock signal to generate a third ramp signal, wherein the third ramp signal corresponds to the period indication signal, wherein a peak of the third ramp signal corresponds to the period indication level, wherein the second ramp signal and the third ramp signal have a phase difference of 180 degrees.

19. The duty ratio correction method of claim 18, wherein the step of generating the clock regeneration signal according to the triggering of the clock signal and a comparison of the first ramp signal with the period indication level includes: comparing the first ramp signal with the second ramp signal and comparing the first ramp signal with the third ramp signal respectively, to generate the clock regeneration signal.

20. The duty ratio correction method of claim 19, wherein the step of generating the first ramp signal according to the clock signal further includes: determining a first charging start point of the first ramp signal according to a state transition point of the clock signal, and determining a timing end point of the first ramp signal according to a first comparison result and a second comparison result, wherein the first comparison result is generated after comparing the first ramp signal with the second ramp signal, wherein the second comparison result is generated after comparing the first ramp signal with the third ramp signal, wherein the target duty ratio corresponds to a ratio of a time difference between the first charging start point and the subsequent timing end point to the period time, wherein the state transition point is one of a rising edge or a falling edge of the clock signal.

21. The duty ratio correction method of claim 20, wherein at a first division state transition point of the frequency divided clock signal, the second current begins charging the second capacitor, and at a second division state transition point of the frequency divided clock signal, the second current stops charging the second capacitor, maintains a voltage across the second capacitor at the period indication level, and resets the second ramp signal according to the first comparison result;
wherein at the second division state transition point of the frequency divided clock signal, the third current begins charging the third capacitor, and at the first division state transition point of the frequency divided clock signal, the third current stops charging the third capacitor, maintains a voltage across the third capacitor at the period indication level, and resets the third ramp signal according to the second comparison result;
wherein the first division state transition point is one of a rising edge or a falling edge of the frequency divided clock signal, wherein the second division state transition point is another of the rising edge or the falling edge of the frequency divided clock signal.

22. The duty ratio correction method of claim 21, wherein the step of resetting the second ramp signal according to the first comparison result further includes: delaying resetting the second ramp signal by a first delay time according to the first comparison result; wherein the step of resetting the third ramp signal according to the second comparison result further includes: delaying resetting the third ramp signal by a second delay time according to the second comparison result.

23. The duty ratio correction method of claim 13, wherein the duty ratio correction method is utilized for a clock signal duty ratio correction circuit which is applied to plural operation circuits coupled to one another in a daisy chain topology, wherein each of the plural operation circuits generates a corresponding output clock signal according to a corresponding input clock signal, wherein the corresponding output clock signal serves as the corresponding input clock signal for an adjacent next operation circuit of the plural operation circuits;
wherein each of the plural operation circuits includes the clock signal duty ratio correction circuit, wherein the clock signal duty ratio correction circuit is configured to generate the clock regeneration signal according to the input clock signal, and to generate the output clock signal according to the clock regeneration signal.

24. The duty ratio correction method of claim 23, wherein each of the plural operation circuits includes at least one state circuit, wherein the at least one state circuit is configured to latch at least one state of the at least one state circuit according to a triggering of the corresponding clock regeneration signal, wherein the at least one state circuit is coupled in a daisy chain topology with at least one state circuit of the adjacent next operation circuit of the plural operation circuits.
